(19) United States
(12) Patent Application Publication
(10) Pub. No.: US 2004/0197710 A1
(43) Pub. Date: Oct. 7, 2004

(54) METHOD FOR DEFINING RING PATTERN

(76) Inventor: Ching-Yu Chang, Yilan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,325

(22) Filed: Apr. 1, 2003

(51) Int. Cl. G03F 7/20

(52) U.S. Cl. 430/315; 430/311; 430/322; 430/324; 430/325; 430/329

(57) ABSTRACT

A method for defining a ring pattern is described, which forms a ring pattern of any shape with only one photomask without misalignment. In the method, a material layer to be defined and a patterned photoresist layer are sequentially formed on a substrate. A silylated photoresist film is formed around the sidewall of the patterned photoresist layer, and then the patterned photoresist layer is removed. The material layer exposed by the silylated photoresist film is removed to form a ring pattern, and then the silylated photoresist film is removed.

### BACKGROUND OF INVENTION

1. Field of the Invention

The present invention relates to a method for patterning a material layer. More particularly, the present invention relates to a method for defining a ring pattern.

2. Description of the Related Art

As dimensions of semiconductor devices continuously decrease, it is more and more difficult to control semiconductor processes and achieve high yields. Particularly, the misalignment problem of current photolithographic processes significantly lowers the yields of semiconductor processes, and also restricts the development in device miniaturization. For example, in a conventional process for defining hollow cylindrical capacitors or crown capacitors that are usually formed in DRAM cells for providing larger areas and storing more charges, the misalignment problem is usually a cause of failure. The reason is that two photolithographic processes are required for defining the inner periphery and the outer periphery, respectively, of each capacitor, while misalignments usually occur between the two photolithographic processes. The misalignment problem becomes more significant as the devices are scaled down.

### SUMMARY OF INVENTION

In view of the forgoing, this invention provides a method for defining a ring patter without misalignment.

This invention also provides a method for defining a lower electrode of a capacitor based on the method for defining a ring patter of this invention, the lower electrode having an increased surface area.

This invention further provides a method for defining a ring pattern that is simpler than the prior art.

This invention further provides a method for defining a ring pattern to overcome the restrictions of photolithographic processes for device miniaturization.

This invention further provides a method for defining a ring pattern that is capable of easily controlling the linewidth of the ring pattern.

The method for defining a ring pattern of this invention is described as follows. A material layer to be defined and a patterned photoresist layer are sequentially formed on a substrate. A silylated photoresist film is formed around the sidewall of the patterned photoresist layer, and then the patterned photoresist layer is removed. The material layer exposed by the silylated photoresist film is removed to form a ring pattern, and then the silylated photoresist film is removed.

In the above-mentioned method of this invention, the process for forming the silylated photoresist film around the sidewall of the patterned photoresist layer may include the following steps. The patterned photoresist layer is subjected to a photoacid reaction with a silicon-containing polymer to form a silylated photoresist film on the exposed surfaces thereof, and then the silylated photoresist film on the top of the patterned photoresist layer is removed.

Besides, the silylated photoresist film around the sidewall of the patterned photoresist layer may be formed with the following steps. A blanket silylated photoresist film is coated on the substrate covering the patterned photoresist layer. Then, the blanket silylated photoresist film is etched back to form a silylated photoresist spacer around the patterned photoresist layer.

On the other hand, a method for defining a lower electrode of a capacitor of this invention is described as follows. A conductive layer and a patterned photoresist layer are sequentially formed on a substrate. A silylated photoresist film is formed around the sidewall of the patterned photoresist layer with a silylation process, and then the conductive layer exposed by the patterned photoresist layer and the first silylated photoresist film is removed. The patterned photoresist layer is removed, and then the exposed conductive layer is partially etched with the silylated photoresist film as a mask to form a lower electrode of a capacitor. Thereafter, the silylated photoresist film is removed.

Another method for defining a lower electrode of a capacitor of this invention is described as follows. A conductive layer and a patterned photoresist layer are sequentially formed on a substrate. A silylated photoresist film is coated on the substrate covering the patterned photoresist layer, and then the silylated photoresist film is etched back to form a silylated photoresist spacer around the patterned photoresist layer. The conductive layer exposed by the patterned photoresist layer and the first silylated photoresist film is removed, and then the patterned photoresist layer is removed. The exposed conductive layer is partially etched with the silylated photoresist spacer as a mask to form a lower electrode of a capacitor, and then the silylated photoresist spacer is removed.

Since a ring pattern is formed with only one photolithographic process in this invention, the misalignment problem encountered in a conventional process using two photolithographic processes can be avoided. Moreover, the linewidth of the ring portion (upper portion) of a lower electrode can be easily controlled by varying the thickness of the silylated photoresist film, and the surface area of the lower electrode therefore can be adjusted as required. Furthermore, the ring pattern may have a square shape, an elliptical shape or a polygonal shape, and two or more concentric ring patterns may also be formed based on the methods of this invention.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1E illustrate a process flow of making a lower electrode of a capacitor according to a preferred embodiment of this invention in a cross-sectional view;

FIG. 2 illustrates a step following the step of FIG. 1E for completing the capacitor in a cross-sectional view; and

FIG. 3 illustrates a top view of two concentric ring patterns that are formed based on the methods of this invention.

### DETAILED DESCRIPTION

The present invention is further explained with a method for forming a lower electrode of a capacitor as an example, but is not restricted to the latter. That is, the present invention can be applied to form a ring pattern of any shape from any conductive or non-conductive material.

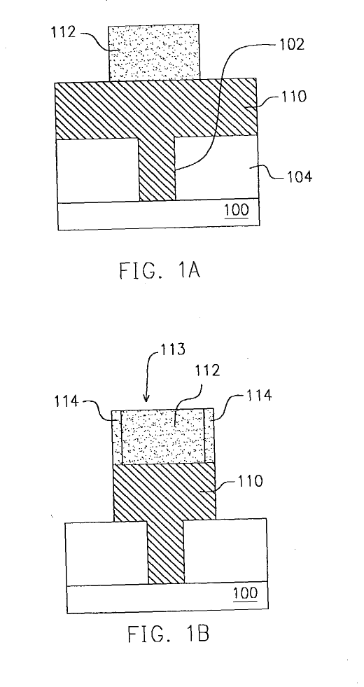

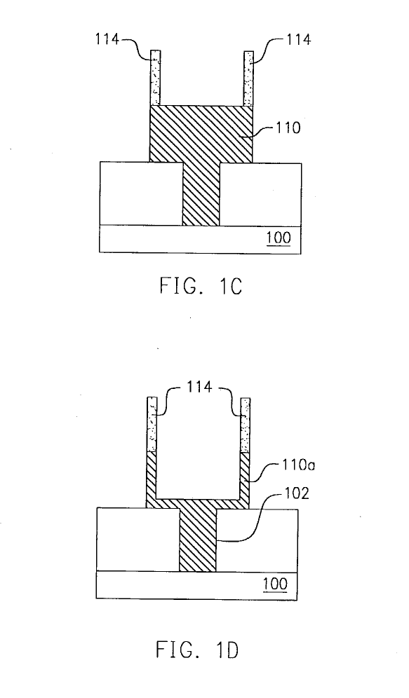

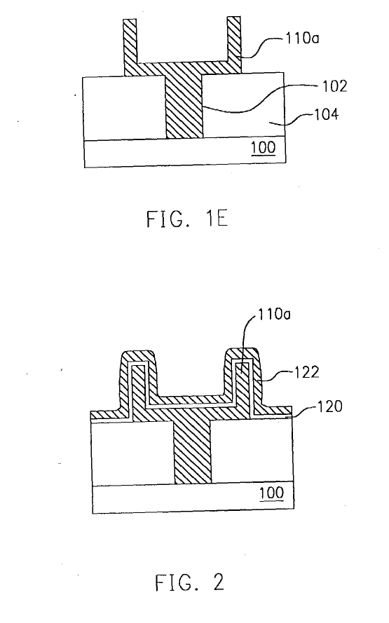

FIGS. 1A-1E illustrate a process flow of making a lower electrode of a capacitor according to a preferred embodiment of this invention in a cross-sectional view.

Referring to FIG. 1A, a substrate 100 is provided including a dielectric layer 104 formed thereon, wherein the dielectric layer 104 has an opening 102 therein, and comprises a material such as silicon oxide. A conductive layer 110, such as a doped polysilicon layer, is formed on the substrate 100 filling up the opening 102. A patterned photoresist layer 112, which comprises a silicon-free polymer, is formed on the conductive layer 110 over the opening 102 with a photolithographic process. The patterned photoresist layer 112 may have a round shape in a top view.

Referring to FIG. 1B, a silylated photoresist film 114 is formed around the sidewall of the patterned photoresist layer 112. A method for forming the silylated photoresist film 114 comprises the following steps. A silylation process is performed to the patterned photoresist layer 112 to form a silylated photoresist film on the exposed surface thereof, wherein the silylation process includes a photoacid reaction of the patterned photoresist layer 112 with a silicon-containing polymer. Then, the silylated photoresist film on the top 113 of the patterned photoresist layer 112 is removed leaving the silylated photoresist film 114. Another method for forming the silylated photoresist film 114 comprises the following steps. A silylated photoresist film is coated on the substrate 100 covering the patterned photoresist layer 112, and is then etched back to form a silylated photoresist spacer, i.e., the silylated photoresist film 114. The etching-back process may use Cl₂/O₂, CF₄/O₂ or CF₄/Cl₂/O₂ as etching gases. Thereafter, the conductive layer 110 exposed by the patterned photoresist layer 112 and the first silylated photoresist film 114 is removed.

Referring to FIG. 1C, the patterned photoresist layer 112 is removed with a method such as reactive ion etching (RIE) or oxygen plasma ashing, while the silylated photoresist film 114 still remains on the conductive layer 110. The silylated photoresist film 114 may shape as a circular ring if the patterned photoresist layer 112 has a round shape in a top view.

Referring to FIG. 1D, the exposed conductive layer 110 is partially etched with the silylated photoresist film 114 as a mask. The etching time is controlled so that the bottom portion of the conductive layer 110 not under the silylated photoresist film 114 still remains, and a lower electrode 110a is formed thereby.

Referring to FIG. 1E, the silylated photoresist film 114 is removed with an etchant such as hydrogen fluoride (HF) or CF₄.

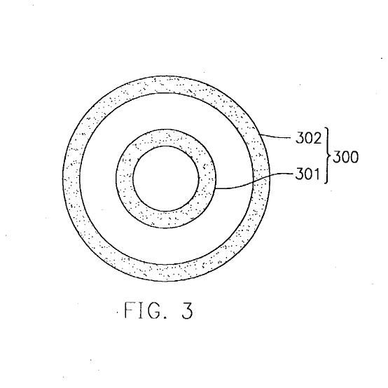

FIG. 2 illustrates a step following the step of FIG. 1E for completing the capacitor.

Referring to FIG. 2, a thin dielectric layer 120 is formed on the substrate 100 covering the lower electrode 110a, and then a conductive layer 122 is formed on the thin dielectric layer 120 serving as an upper electrode of the capacitor.

Except the aforementioned lower electrode of capacitor, the method of this invention can be used to form a ring pattern of any shape like square shape, elliptical shape or polygonal shape, or even two concentric ring patterns. FIG. 3 illustrates a top view of such a pair of concentric ring patterns 300, which includes an inner ring pattern 301 and an outer ring pattern 302 both having a circular shape in a top view. Nevertheless, the inner ring pattern or the outer ring pattern is not restricted to form as a circular ring, and may be formed as a square ring, an elliptical ring or a polygonal ring. In addition, the inner ring pattern and the outer ring pattern may have different shapes. Furthermore, the number of the concentric ring patterns is not restricted to “2” as in the case of FIG. 3, and may be an integer larger than 2. That is, this invention can be applied to form multi concentric ring patterns.

Since a ring pattern is formed with only one photolithographic process in this invention, the misalignment problem encountered in a conventional process using two photolithographic processes can be avoided. Moreover, the linewidth of the ring portion of a lower electrode can be easily controlled by varying the thickness of the silylated photoresist film, and the surface area of the lower electrode therefore can be adjusted as required. For example, by decreasing the thickness of the silylated photoresist film, the surface area of the lower electrode can be increased since the inner surface area of the lower electrode is increased more than the top surface area thereof is decreased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A method for defining a ring pattern, comprising:
forming a material layer on a substrate;
forming a patterned photoresist layer on the material layer;
forming a first silylated photoresist film around the sidewall of the patterned photoresist layer;
removing the patterned photoresist layer;
removing the material layer exposed by the first silylated photoresist film to form a ring pattern; and
removing the first silylated photoresist film.

2. The method of claim 1, wherein forming the silylated photoresist film around the sidewall of the patterned photoresist layer comprises:
performing a silylation process to the patterned photoresist layer to form a second silylated photoresist film on exposed surfaces of the patterned photoresist layer; and
removing the second silylated photoresist film on a top of the patterned photoresist layer to form the first silylation photoresist film from the second silylated photoresist film.

3. The method of claim 2, wherein the silylation process comprises a photoacid reaction of the patterned photoresist layer with a silicon-containing polymer.

4. The method of claim 1, wherein forming a silylated photoresist film around the sidewall of the patterned photoresist layer comprises:
coating the substrate with a second silylated photoresist film covering the patterned photoresist layer; and
etching back the second silylated photoresist film to form a silylated photoresist spacer as the first silylated photoresist film.

5. The method of claim 1, wherein removing the first silylated photoresist film comprises using hydrogen fluoride (HF) to remove the first silylated photoresist film.

6. The method of claim 1, wherein removing the patterned photoresist layer comprises performing a reactive ion etching (RIE) process.

7. The method of claim 1, wherein removing the patterned photoresist layer comprises using oxygen plasma to remove the patterned photoresist layer.

8. The method of claim 1, wherein the material layer comprises a conductive layer.

9. The method of claim 8, wherein the conductive layer comprises doped polysilicon.

10. The method of claim 1, wherein the patterned photoresist layer comprises a silicon-free polymer.

11. A method for defining a lower electrode of a capacitor, comprising:
forming a conductive layer on a substrate;
forming a patterned photoresist layer on the conductive layer;
forming a first silylated photoresist film around the sidewall of the patterned photoresist layer;
removing the conductive layer exposed by the patterned photoresist layer and the first silylated photoresist film;
removing the patterned photoresist layer;
removing a portion of the conductive layer exposed by the first silylated photoresist film to form a lower electrode; and
removing the first silylated photoresist film.

12. The method of claim 11, wherein forming the silylated photoresist film around the sidewall of the patterned photoresist layer comprises:
performing a silylation process to the patterned photoresist layer to form a second silylated photoresist film on exposed surfaces of the patterned photoresist layer; and
removing the second silylated photoresist film on a top of the patterned photoresist layer to form the first silylation photoresist film from the second silylated photoresist film.

13. The method of claim 12, wherein the silylation process comprises a photoacid reaction of the patterned photoresist layer with a silicon-containing polymer.

14. The method of claim 11, wherein removing the first silylated photoresist film comprises using hydrogen fluoride (HF) to remove the first silylated photoresist film.

15. The method of claim 11, wherein removing the patterned photoresist layer comprises performing a reactive ion etching (RIE) process.

16. The method of claim 11, wherein removing the patterned photoresist layer comprises using oxygen plasma to remove the patterned photoresist layer.

17. The method of claim 11, wherein the conductive layer comprises doped polysilicon.

18. The method of claim 11, wherein the patterned photoresist layer comprises a silicon-free polymer.

19. The method of claim 11, wherein forming the silylated photoresist film around the sidewall of the patterned photoresist layer comprises:
coating the substrate with a second silylated photoresist film covering the patterned photoresist layer; and
etching back the second silylated photoresist film to form a silylated photoresist spacer as the first silylated photoresist film.

20. The method of claim 19, wherein etching back the second silylated photoresist film comprises using Cl₂ and O₂ as etching gases.
